(19) United States
(12) Patent Application Publication
(10) Pub. No.: US 2026/0026067 A1
(43) Pub. Date: Jan. 22, 2026

(54) Semiconductor structure and forming method thereof

(71) Applicant: UNITED MICROELECTRONICS CORP., Hsin-Chu City (TW)

(72) Inventors: Shen-De Wang, Hsinchu County (TW); Purakh Raj Verma, Singapore (SG)

(73) Assignee: UNITED MICROELECTRONICS CORP., Hsin-Chu City (TW)

(21) Appl. No.: 18/800,145

(22) Filed: Aug. 12, 2024

(30) Foreign Application Priority Data
Jul. 16, 2024 (TW) 113126572

(51) Int. Cl. H01L 29/40; H01L 27/06; H01L 29/66; H01L 29/78

(52) U.S. Cl. CPC H10D 64/112; H10D 1/47; H10D 30/0281; H10D 30/65; H10D 84/811

(57) ABSTRACT

The invention provides a semiconductor structure, which comprises a substrate, an oxide layer located on a surface of the substrate, a gate electrode located on the substrate and partially contacting the substrate, a first field plate located on the oxide layer, a first dielectric layer covering the gate electrode, a second dielectric layer located on the first dielectric layer, a second field plate located between the first dielectric layer and the second dielectric layer, and a third field plate located on the second dielectric layer, wherein a horizontal position of the second field plate is located between a horizontal position of the first field plate and a horizontal position of the third field plate when viewed from a sectional view.

### BACKGROUND OF THE INVENTION

### 1. Field of the Invention

The present invention relates to a high voltage metal-oxide-semiconductor (hereinafter referred to as HV MOS) transistor element, in particular to a high voltage lateral double-diffused metal-oxide-semiconductor (HV-LDMOS) transistor element with a filed plate with a special shape.

### 2. Description of the Prior Art

Double-diffused MOS (DMOS) transistor devices have been paid more and more attention among power devices with high voltage processing capability. Common DMOS transistor elements are vertical double-diffused MOS (VDMOS) and horizontal double-diffused MOS (LDMOS). LDMOS transistor elements have been widely used in high-voltage operating environment, such as CPU power supply, power management system, DC/AC/DC converter, high-power or high-frequency power amplifier, etc., because of their high operating bandwidth and operating efficiency, and the planar structure that is easy to integrate with other integrated circuits. The LDMOS transistor element is mainly characterized by a low doping concentration and a large lateral diffusion drift region at the source terminal, which aims to alleviate the high voltage between the source terminal and the drain terminal, so that the LDMOS transistor element can obtain a higher breakdown voltage.

Because the two main characteristics pursued by HV MOS transistor elements are low on-resistance and high breakdown voltage, and these two requirements are often conflicting and difficult to weigh. Therefore, there is still a need for a solution that can operate normally in high voltage environment and meet the requirements of low on-resistance and high breakdown voltage at the same time. In addition, the electrostatic discharge (ESD) of HV MOS transistor elements will also affect the overall performance, so reducing the ESD of HV MOS transistor elements is also an important issue.

Field plate is a common structure in semiconductor devices, especially in high voltage semiconductor devices. It is usually a conductive layer placed on the edge of the active area of the device, which is used to control the electric field distribution and improve the performance of the device. The field plate is usually made of metal or polysilicon with good conductivity. The field plate is usually placed at the edge of the drift region of the device and covers the PN junction. The field plate can be in various shapes, such as plane, step or curved surface, depending on the component design and improvement goal.

The main function of the field plate is to control the electric field distribution at the edge of the drift region of the element. By adjusting the shape, thickness and material of the field plate, the electric field intensity at the edge of the drift region can be effectively reduced, thus improving the breakdown voltage of the device. Under high voltage, the electric field lines tend to concentrate at the sharp corner of PN junction, resulting in too high electric field intensity and easy breakdown. Field plate can effectively alleviate this electric field concentration phenomenon and improve the reliability of components. Field plate can also optimize the switching characteristics of components, such as reducing on-resistance and shortening switching time.

However, at present, the fabrication of field plates also faces some challenges. For example, the fabrication of field plates requires additional process steps, such as deposition, etching and annealing, which increases the manufacturing cost of components. Parasitic capacitance will be formed between the field plate and other parts of the device, which will affect the high frequency performance of the device. The design of field plate needs to consider many factors, such as element structure, material characteristics, electric field distribution, etc., and needs complex simulation and improvement. In a word, field plate is an important structure in semiconductor devices. By controlling the electric field distribution, the breakdown voltage, reliability and switching performance of the devices can be effectively improved. However, the manufacture and design of the field board are also facing some challenges and need further research and development.

### SUMMARY OF THE INVENTION

The invention provides a semiconductor structure, which comprises a substrate, an oxide layer located on a surface of the substrate, a gate electrode located on the substrate and partially contacting the substrate, a first field plate located on the oxide layer, a first dielectric layer covering the gate electrode, a second dielectric layer located on the first dielectric layer, a second field plate is located between the first dielectric layer and the second dielectric layer, and a third field plate is located on the second dielectric layer, wherein a horizontal position of the second field plate is located between a horizontal position of the first field plate and a horizontal position of the third field plate when viewed from a sectional view.

The invention further provides a semiconductor structure, which comprises a substrate, an oxide layer located on a surface of the substrate, a gate electrode located on the substrate and partially contacting the substrate, a first field plate located on the oxide layer, and a third field plate located above the first field plate, wherein the third field plate presents a comb shape when viewed from a top view, and the third field plate comprises a main shaft part extending along a first direction and a plurality of branch parts extending along a second direction, wherein the branch parts are connected with the main shaft part.

The invention also provides a method for forming a semiconductor structure, which comprises providing a substrate, forming an oxide layer on one surface of the substrate, forming a gate electrode on the substrate and partially contacting the substrate, forming a first field plate on the oxide layer, forming a first dielectric layer on the oxide layer, covering the gate electrode, and forming a second field plate located between the first dielectric layer and the second dielectric layer, and forming a third field plate located on the second dielectric layer, wherein a horizontal position of the second field plate is located between a horizontal position of the first field plate and a horizontal position of the third field plate when viewed from a sectional view.

To sum up, the invention is characterized in that the field plate located in LDMOS can regulate the electric field in the drift region and reduce the probability of electric field breakdown, so it is an important element in LDMOS. However, the applicant found that the larger the field plate is designed, the more effectively the electric field in the drift region can be controlled, but at the same time, it may also increase the field plate too close to the drain doped region, so that the electric field in the drain doped region will affect the field plate. Therefore, in some embodiments of the present invention, an improved semiconductor structure is proposed, especially a high-voltage lateral double-diffused metal-oxide-semiconductor (HV-LDMOS) transistor element with multiple field plates. In some embodiments, the second field plate is located between the two dielectric layers above the drift region, so the second field plate can not only control the electric field of the drift region, but also avoid the problem of TDDB caused by being too close to the drain doped region. In other embodiments of the present invention, the fourth field plate is located above the dielectric layer and connected to the second field plate, further reducing the occurrence probability of TDDB in the drain doped region. In other embodiments of the present invention, the shape of the third field plate is designed, for example, it is designed as a comb shape, so that the overall resistance of the semiconductor structure can be reduced. The embodiments provided by the invention have the advantages of improving the quality of semiconductor elements and the electric energy conversion efficiency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present t specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIG. 1 is a schematic cross-sectional view of a semiconductor structure according to a first embodiment of the present invention.

FIG. 2, FIG. 3 and FIG. 4 are schematic cross-sectional views of a semiconductor structure forming a second embodiment of the present invention.

FIG. 5 is a schematic cross-sectional view of a semiconductor structure according to a third embodiment of the present invention.

FIG. 6 is a schematic cross-sectional view of a semiconductor structure according to a fourth embodiment of the present invention.

FIG. 7 is a top view of the metal layer, the gate electrode and the field plate in FIG. 6.

FIG. 8 is a top view of a metal layer, the gate electrode and the field plate of a semiconductor structure according to a fifth embodiment of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about” or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

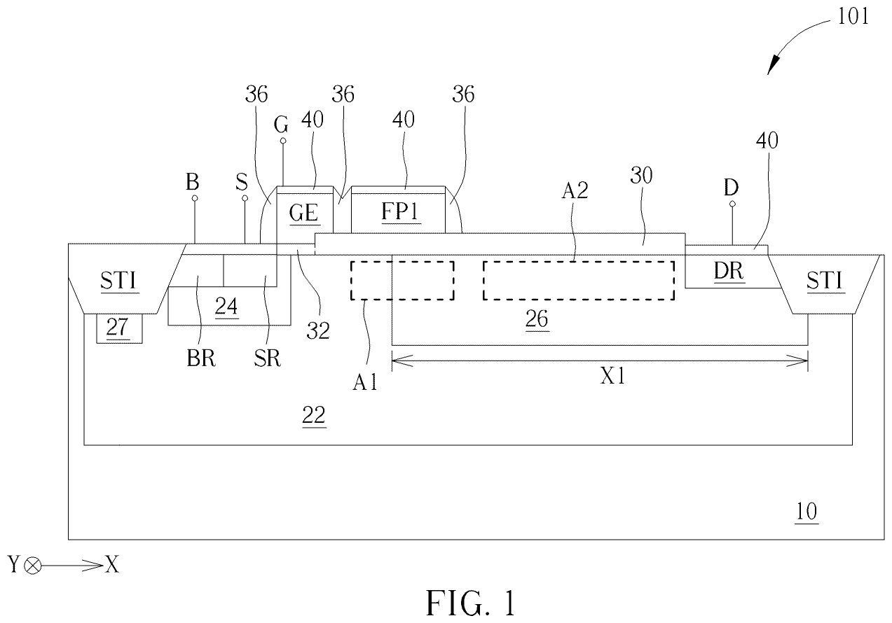

Please refer to FIG. 1. FIG. 1 is a schematic cross-sectional view of a semiconductor structure according to a first embodiment of the present invention. As shown in FIG. 1, this embodiment provides a semiconductor structure 101 including a substrate 10. The substrate 10 contains a source doped region SR, a drain doped region DR and a gate electrode GE, which are connected with the source S, the drain D and the gate G, respectively, to form the smallest unit of a lateral double diffused metal-oxide-semiconductor (LDMOS) transistor. The semiconductor structure 101 shown in FIG. 1 includes the smallest unit of an LDMOS transistor, which will be described in detail in the following paragraphs.

In some embodiments, the substrate 10 may include a silicon substrate, an epitaxial silicon substrate, a silicon germanium substrate, a silicon carbide substrate, a silicon-on-insulator (SOI) substrate or a semiconductor substrate formed of other suitable semiconductor materials and/or structures, but the present invention is not limited thereto.

Referring to FIG. 1, the substrate 10 at least includes a deep well region 22, a doped well region 24, a drift region 26, a drift region 27 and a shallow trench isolation STI. The shallow trench isolation STI may be partially disposed in the substrate 10 to define a plurality of active area (not labeled in FIG. 1) in the substrate 10, and the shallow trench isolation STI may include a single layer or multiple layers of insulating materials such as oxide insulating materials (such as silicon oxide) or other suitable insulating materials.

The deep well region 22, the doped well region 24, the drift region 26 and the drift region 27 may be disposed in the substrate 10 and may be doped regions formed in the substrate 10 by a doping process (such as an implantation process). The deep well region 22 can be located in the substrate 10, the doped well region 24 is surrounded by the deep well region 22, and the drift region 26 can be located above the deep well region 22, and the drift region 27 is located in the deep well region 22 and below the shallow trench isolation STI next to the doped well region 24. In some embodiments, the doped well region 24 may have a first conductivity type, while the deep well region 22, the drift region 26 and the drift region 27 may have a second conductivity type, wherein the first conductivity type is complementary to the second conductivity type. For this embodiment, when the substrate 10 is a P-type semiconductor substrate or a substrate with a P-type doped region, the deep well region 22 can be an N-type doped deep well region, the doped well region 24 can be a P-type doped well region, and the drift region 26 and the drift region 27 can be N-type doped regions, but not limited thereto. In some embodiments, an N-type substrate 10 or a substrate 10 with an N-type doped region can also be used according to design requirements, and the conductivity types of the above-mentioned well regions and doped regions can be adjusted accordingly.

In addition, the semiconductor structure 101 may further include a body doped region BR. The body doped region BR and the source doped region SR may be disposed in the doped well region 24, and the drain doped region DR may be disposed in the drift region 26. The source doped region SR, the drain doped region DR, and the body doped region BR may be doped regions formed in the substrate 10 by a doping process (such as an implantation process), respectively. For example, the source doped region SR and the drain doped region DR may be heavily doped regions with the same conductivity type as the drift region 26 (for example, heavily N-type doped regions), and the body doped region BR may be heavily doped regions with the same conductivity type as the doped well region 24 (for example, heavily P-type doped regions), but it is not limited thereto. In some embodiments, the body doped region BR can be used to adjust the potential of the doped well region 24 and connected to a body B. The body doped region BR and the source doped region SR can be regarded as the source doped region in the semiconductor structure 101 together. From FIG. 1, the body doped region BR is connected to the source doped region SR, so they are equipotential, and FIG. 1 shows that the body B and the source S are connected to the body doped region BR, which also means that the body B and the source S are connected to the source doped region BR.

In the above embodiment, the function of the deep well region 22 is to form an independent N-shaped region for isolating different elements and preventing mutual interference. The function of the doped well region 24 is to provide a base for forming an N-type channel, and when the LDMOS is off, the holes in the doped well region 24 help to deplete the electrons in the drift region 26 and ensure that the LDMOS is off. The function of drift region 26 is that when LDMOS is on, electrons form a conductive channel in the drift region 26, allowing current to flow from source S to drain D. The length and doping concentration of drift region 26 directly affect the on-resistance of LDMOS.

Referring to FIG. 1, a semiconductor structure 101 includes a gate electrode GE, a source doped region SR, a drain doped region DR, an oxide layer 30, a gate dielectric layer 32 and a field plate) FP1. Here, the gate electrode GE, the gate dielectric layer 32, the oxide layer 30, the first field plate FP1, the source doped region SR, the drain doped region DR and the drift region 26 are combined to form a high-voltage semiconductor device, and this high-voltage semiconductor device may include, but is not limited to, the lateral double diffused metal oxide semiconductor (LDMOS) transistor.

The gate electrode GE is arranged on the substrate 10 and used as the gate in LDMOS. The source doped region SR and the drain doped region DR are disposed in the substrate 10 and located on two opposite sides of the gate electrode GE in a horizontal direction (such as the X direction in FIG. 1). The oxide layer 30 is disposed on part of the deep well region 22, part of the drift region 26 and part of the drain doped region DR of the substrate 10, and extends from the gate electrode GE to the drain doped region DR. In addition, in this embodiment, a part of the oxide layer 30 is covered by the gate electrode GE, and the other part is in contact with the drain doped region DR. That is, from the cross-sectional view, a part of the gate electrode GE is located on the gate dielectric layer 32, while another part of the gate electrode GE is covered on the oxide layer 30. The junction between the gate dielectric layer 32 and the oxide layer 30 has a stepped cross-sectional shape (that is, a height difference shape), and this stepped structure is located directly below the gate electrode GE. In this embodiment, the material of the oxide layer 30 includes silicon oxide, and the gate dielectric layer 32 may include oxide (such as silicon oxide), high-k dielectric material or other suitable dielectric materials. The high-k dielectric material may include hafnium oxide (HfO), hafnium silicon oxide (HfSiO₄), hafnium silicon oxynitride (HfSiON), aluminum oxide (alumina), Al₂O₃), tantalum oxide (Ta₂O₅), zirconium oxide (ZrO₂) or other suitable high dielectric constant materials.

In this embodiment, the gate dielectric layer 32 and the oxide layer 30 can also contain the same material (for example, both are silicon oxide), that is, the gate dielectric layer 32 and the oxide layer 30 can be regarded as a stepped oxide layer. In the actual process, an oxide layer with a first thickness can be formed as the gate dielectric layer 32 on the substrate by the first oxidation growth step, for example, the thickness is 30-200 angstroms, but it is not limited to this. Then, another oxidation generation step is carried out, and a thicker oxide layer is continuously generated on a part of the oxide layer with the first thickness, so as to form the stepped gate dielectric layer 32 and the oxide layer 30 as shown in FIG. 1.

The first field plate FP1 is one of the important components of LDMOS. The first field plate FP1 is located on the oxide layer 30. In this embodiment, the first field plate FP1 is also preferably located at the junction of the deep well region 22 and the drift region 26. The first field plate FP1 has the following functions: firstly, it can effectively control the electric field distribution of the drift region 26. By changing the bias voltage of the first field plate FP1, the electric field intensity of the drift region 26 can be influenced, and then the movement of carriers (electrons) in the drift region 26 can be controlled. This has an important influence on the switching characteristics and on-resistance of LDMOS. Taking this embodiment as an example, in the actual control process, the first field plate FP1 controls the electric field below by applying a bias voltage on it. When a positive bias is applied to the field plate, it will attract electrons in the drift region 26, thus reducing the electric field intensity in this region. On the contrary, when a negative bias is applied to the field plate, it will repel electrons and increase the electric field intensity of the drift region 26. In addition, under high voltage, the drift region 26 is prone to electric field breakdown. The first field plate FP1 can effectively reduce the electric field intensity of the drift region 26, thereby increasing the breakdown voltage of LDMOS and enhancing its withstand voltage. In addition, the existence of the first field plate FP1 can expand the control range of the gate G to the drift region 26, improve the control ability of the gate G to the channel, and further improve the switching speed and dynamic performance of LDMOS.

In addition, the first field plate FP1, the gate electrode GE, the body doped region BR, the source doped region SR, and the drain doped region DR may optionally include a metal silicide layer 40, wherein the main function of the metal silicide layer 40 is to reduce the contact resistance, that is to say, by forming the metal silicide layer 40, silicon (including the gate electrode GE and the substrate 10) and subsequent contact structures (such as metal) can be reduced. In addition, in some embodiments, the formation of the metal silicide layer 40 may also have the effects of improving the current density (allowing higher current density to pass because of the lower contact resistance, so that LDMOS can work at higher current) and improving thermal stability. However, in other embodiments of the present invention, it is also possible to omit the metal silicide layer 40, which is also within the scope of the present invention.

In some embodiments, the gate electrode GE may include a non-metallic conductive material (e.g., doped polysilicon) or a metallic conductive material, such as a metal gate electrode stacked by a work function layer and a low resistance layer, and the first field plate FP1 may include a non-metallic conductive material (e.g., doped polysilicon) or a metallic conductive material. Therefore, in some embodiments, the material composition of the first field plate FP1 can be the same as that of the gate electrode GE, thereby simplifying the related process steps (for example, when the first field plate FP1 and the gate electrode GE are both formed of polysilicon, the required metal silicide layer 40 can be formed on the polysilicon together, but not limited thereto). However, in some embodiments, the first field plate FP1 and the gate electrode GE with different material compositions can also be used according to design requirements. In addition, in some embodiments, the semiconductor structure 101 may further include a spacer 36, which may be disposed on the sidewall of the gate electrode GE and the first field plate FP1, and the spacer 36 may include a single layer or multiple layers of dielectric materials, such as silicon oxide, silicon nitride, silicon oxynitride or other suitable dielectric materials.

Through the arrangement of the above elements, the effect of reducing the on-resistance (Ron) of the semiconductor structure 101 and/or adjusting the electric field distribution can be achieved, thereby improving the electrical performance of the semiconductor structure 101. In some embodiments, by electrically connecting the first field plate FP1 with the gate electrode GE, the on-resistance of the semiconductor structure 101 can be reduced, so that the intensity of the electric field generated by the semiconductor structure 101 on the surface of the substrate 10 can be reduced and the electric field distribution can be homogenized, thereby improving the related electrical performance of the semiconductor structure 101.

However, with the development of technology, the density of components per unit volume is getting higher and higher, and the gap between components is getting smaller and smaller. The applicant found that some problems may occur when making LDMOS with larger size, that is, the LDMOS with larger size will have wider drift region, but if the field plate is not extended, the electric field in the large drift region cannot be completely controlled. On the other hand, if the field plate is extended over the whole drift region, the extended field plate will be closer to the drain doped region, so the possibility of time-dependent dielectric breakdown (TDDB) will be increased.

Explaining with a practical example, from FIG. 1, the width X1 of the drift region 26 in the X direction is relatively large, while the width of the first field plate FP1 is relatively short, so it cannot be located above the complete drift region 26, which leads to that the first field plate FP1 cannot completely control the electric field in the drift region 26. For example, the first field plate FP1 is located just above the region A1, so it can control the electric field at the region A1. However, since the first field plate FP1 is not located directly above the region A2, the electric field at the region A2 cannot be controlled.

However, if the size of the first field plate FP1 is increased to extend directly above the region A2, it will cause another hidden danger, that is, the extended first field plate FP1 will be closer to the drain doped region DR. In LDMOS, high-voltage electric fields are easily generated at the gate electrode GE, the source doped region SR and the drain doped region DR. Therefore, time-dependent dielectric breakdown (TDDB) will easily occur near the drain doped region DR, making the electric field penetrate through the dielectric.

In the following, different embodiments of the semiconductor structure and its manufacturing method of the present invention will be described, and in order to simplify the description, the following description will mainly focus on the differences of each embodiment, and will not repeat the similarities. In addition, the same elements in various embodiments of the present invention are labeled with the same reference numerals, so as to facilitate the comparison among various embodiments.

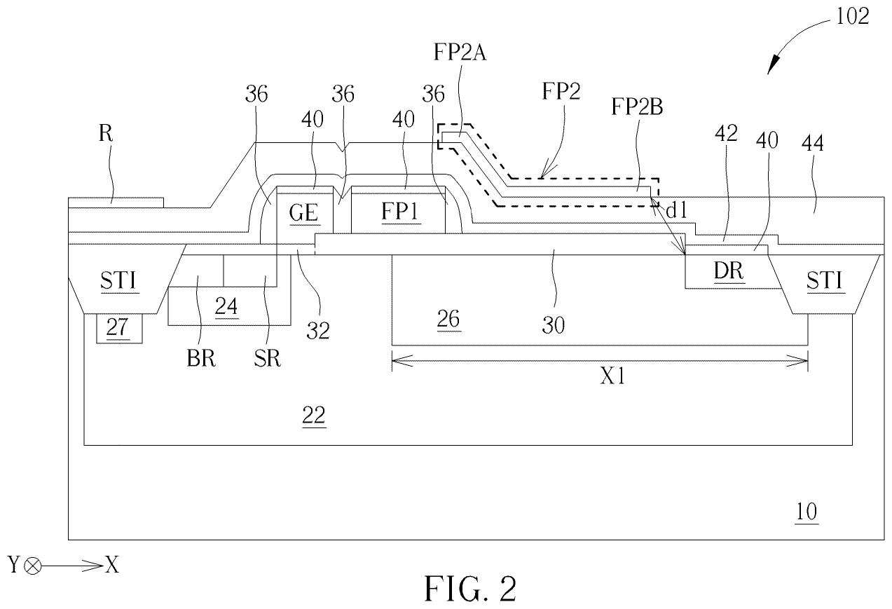

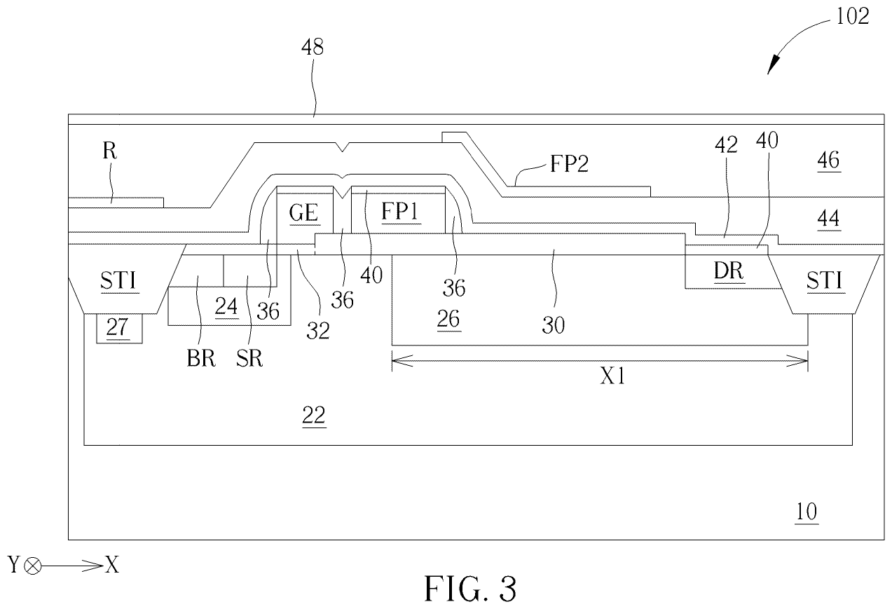

In order to improve the above problems, other embodiments of the present invention provide some improved semiconductor structures. Please refer to FIG. 2 to FIG. 4, which are schematic cross-sectional views of a semiconductor structure forming a second embodiment of the present invention. Among them, the semiconductor structure 102 of the second embodiment of the present invention is based on the structure of the semiconductor structure 101 of the first embodiment to form subsequent other elements, so most of the elements are the same as those of the first embodiment, and these same elements will not be repeated. As shown in FIG. 2, based on the semiconductor structure of the first embodiment, a contact etch stop layer (CESL) 42 and a first dielectric layer 44 are continuously formed on the surface of the substrate 10, wherein the contact etch stop layer 42 and the first dielectric layer 44 conformally cover the shallow trench isolation STI, the metal silicide layer 40, the gate electrode GE, the first field plate FP1, the oxide layer 30, etc. The material of the contact etch stop layer 42 here is, for example, silicon nitride or silicon oxide, but it is not limited thereto. The material of the first dielectric layer 44 is, for example, USGB (undoped silicate glass) or other suitable oxides, and the thickness of the first dielectric layer 44 is about 2000 to 4000 angstroms, but the present invention is not limited to this.

Referring to FIG. 2, a resistance layer R and a second field plate FP2 are formed on the surface of the first dielectric layer 44. The resistance layer R and the second field plate FP2 can be formed by depositing a material layer on the first dielectric layer 44, and then partially removing the material layer through a photolithography etching step, and the remaining material layers after the etching step are the resistance layer R and the second field plate FP2. That is to say, in this embodiment, the second field plate FP2 and the resistance layer R can be formed at the same time, and both of them contain the same material. In this embodiment, the material of the second field plate FP2 or the resistance layer R may include TiN (titanium nitride) or TaN (tantalum nitride), for example, but the present invention is not limited to this, and the materials of the resistance layer R and the second field plate FP2 may be adjusted according to actual needs.

It is worth noting that the second field plate FP2 is located on the first dielectric layer 44. Seen from the cross section, the second field plate FP2 is located right above the partial drift region 26. In the following steps, the second field plate FP2 can be electrically connected with the first field plate FP1, that is to say, the second field plate FP2 formed here can also be regarded as an extension of the original first field plate FP1. Therefore, when a bias is applied to the first field plate FP1, the second field plate FP2 is equipotential with the first field plate FP1 to control the electric field in the drift region 26. Or in other embodiments, the first field plate FP1 and the second field plate FP2 do not have to be electrically connected with each other, so different voltage sources can be provided to the first field plate FP1 and the second field plate FP2, so that the bias voltages of the first field plate FP1 and the second field plate FP2 can respectively affect the electric field in the lower drift region 26, and the effect of controlling the electric field in the drift region 26 can also be achieved. Therefore, the second field plate FP2 of the present invention can be used to control the electric field in the drift region 26 which cannot be completely controlled by the first field plate FP1. Besides, the second field plate FP2 is located above the first dielectric layer 44, so it is far away from the drain doped region DR. As shown in FIG. 2, the distance between the second field plate FP2 and the drain doped region DR is defined as d1, and the manufacturer can adjust the distance d1 by adjusting the thickness of the first dielectric layer 44 or the length of the second field plate FP2. Since the first dielectric layer 44 is located between the second field plate FP2 and the drain doped region DR, and the first dielectric layer 44 itself has a certain thickness (for example, more than 2000 angstroms), so the high voltage in the drain doped region DR is less likely to break through the first dielectric layer 44 and affect the second field plate FP2. In other words, the second field plate FP2 in this embodiment can not only control the electric field in the drift region 26, but also reduce the probability that the second field plate FP2 is affected by TDDB in the drain doped region DR.

In addition to the above features, the second field plate FP2 and the resistance layer R in this embodiment also contain other features. For example, as shown in FIG. 2, because the oxide layer 30 on the surface of the substrate 10 has a certain thickness, after the contact etching stop layer 42 and the first dielectric layer 44 cover the surface of the substrate 10, the second field plate FP2 is located on a higher horizontal plane, that is, the horizontal position of the second field plate FP2 will be higher than the resistance layer when viewed from the horizontal direction. It is worth noting that the resistance layer R here is, for example, a thin film resistance layer used in semiconductor devices, so in some embodiments, when the semiconductor structure contains the thin film resistance layer, the resistance layer R can be formed at the same time as the second field plate FP2 to save the process steps. It can be understood that if the semiconductor structure does not include a thin film resistance layer in other embodiments, the resistance layer R can also be omitted here, that is, only the second field plate FP2 may be formed on the first dielectric layer 44, and this variation structure is also within the scope of the present invention.

In addition, as seen from FIG. 2, in this embodiment, because the first dielectric layer 44 covers the lower element such as the first field plate FP1, and the second field plate FP2 covers the first dielectric layer 44, the cross-sectional profile of the second field plate FP2 is similar to or the same as the cross-sectional profile of the lower covered element. Taking this embodiment as an example, part of the second field plate FP2 is located on the protruding first dielectric layer 44, so the second field plate FP2 includes a first part FP2A extending in an oblique direction and a second part FP2B extending in a horizontal direction. However, it is worth noting that the second field plate FP2 in this embodiment only needs to be located on the first dielectric layer 44 and directly above the partial drift region 26, and the length of the second field plate FP2 can be adjusted as required. Therefore, in some embodiments, the second field plate FP2 may not be located on the protruding first dielectric layer 44, and in these embodiments, the second field plate FP2 may only contain the horizontal part and not contain the oblique part.

Referring to FIGS. 3 and 4, as shown in FIG. 3, the second dielectric layer 46 is formed on the first dielectric layer 44, the resistance layer R and the second field plate FP2, and then a planarization step (such as chemical mechanical polishing (CMP)) is performed, and then a cap layer 48 is formed on the second dielectric layer 46. The material of the second dielectric layer 46 here is, for example, PSG (phosphosilicate glass), TEOS (tetraethoxysilane) or other suitable oxide materials, and the thickness of the second dielectric layer 46 is about 1000 to 4000 angstroms, but it is not limited to this. As for the material of the cap layer 48, for example, silicon nitride (SiCN) can be used, but it is not limited to this.

As shown in FIG. 4, a plurality of contact structures CT are then formed, which penetrate through the lower material layers such as the second dielectric layer 46, the first dielectric layer 44, and the contact etching stop layer 42, and then electrically connect the lower elements such as the resistance layer R, the first field plate FP1, the second field plate FP2, the gate electrode GE, the source doped region SR, the drain doped region DR, etc. The material of the contact structure CT includes, for example, tungsten, cobalt, copper, aluminum, gold, silver and other metals with good conductivity, but is not limited to this. Next, a dielectric layer 50 is formed over the second dielectric layer 46, and a plurality of patterned first metal layers M1 are formed in the dielectric layer. The dielectric layer 50 is made of insulating materials such as silicon oxide, silicon nitride and silicon oxynitride, but it is not limited to this. As for the first metal layer M1, it may be a patterned metal layer formed in the dielectric layer 50. The main function of the first metal layer M1 is to connect various elements below, such as the resistance layer R, the first field plate FP1, the second field plate FP2, the gate electrode GE, the source doped region SR, the drain doped region DR, etc., to other elements formed subsequently, or to connect the above elements with each other. It is worth noting that in this embodiment, part of the first metal layer M1 connects the lower first field plate FP1 and the second field plate FP2 through the contact structure, so this part of the first metal layer M1 can also be regarded as a part of the field plate. In other words, a voltage source may be provided to the first field plate FP1 in the following steps, and at this time, the voltage source can be electrically connected to the adjacent second field plate FP2 through the upper first metal layer M1, so as to achieve the effect of controlling the electric field in the lower drift region. For clearer description, the first metal layer M1 connected to the first field plate FP1 and the second field plate FP2 is defined as the third field plate FP3. It is worth noting that the third field plate FP3 in this embodiment is aligned with other first metal layers M1 in the horizontal direction, and the third field plate FP3 contains the same material as other first metal layers M1.

Therefore, as shown in FIG. 4, the semiconductor structure 102 in the second embodiment of the present invention has additional second field plates FP2 compared with the semiconductor structure 101 in the first embodiment. Wherein the second field plate FP2 is located between the first dielectric layer 44 and the second dielectric layer 46. The second field plate FP2 extends over a part of the drift region 26, so the electric field of the drift region 26 can be controlled by applying a bias voltage to the second field plate FP2 in the subsequent step, especially the part of the drift region 26 that cannot be controlled by the first field plate FP1. In addition, compared with extending the first field plate FP1 directly, the second field plate FP2 additionally arranged in this embodiment is farther away from the drain doped region DR, so the TDDB problem caused by the drain doped region DR can be effectively reduced, and the stability of the semiconductor structure can be further improved.

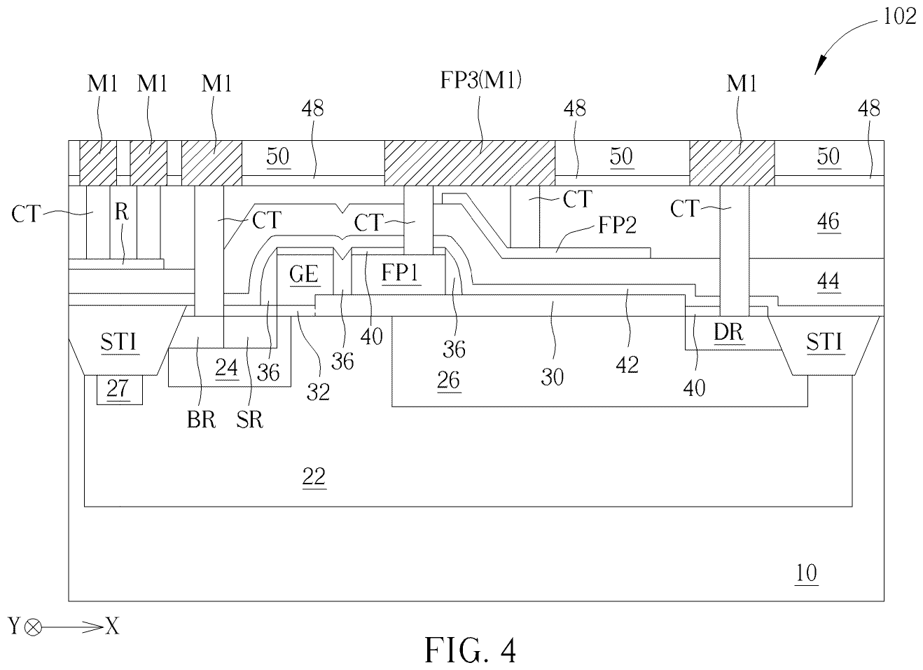

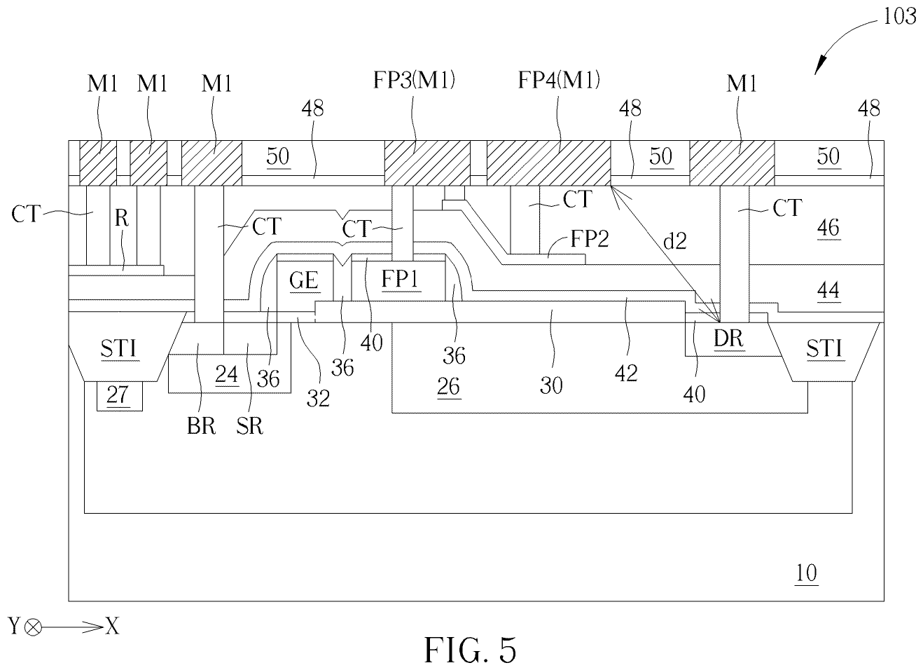

Next, please refer to FIG. 5, which shows a schematic cross-sectional structure of a semiconductor structure according to a third embodiment of the present invention. As shown in FIG. 5, this embodiment provides a semiconductor structure 103, in which most elements are the same as the semiconductor structure 102 shown in the second embodiment (refer to FIG. 4), so the repeated elements will not be described in detail. The main difference between this embodiment and the previous embodiment is that one part of the first metal layer M1 in this embodiment is defined as a third field plate FP3, and another part of the first metal layer M1 is defined as a fourth field plate FP4. As mentioned above, the third field plate FP3 is electrically connected to the first field plate FP1 and the second field plate FP2 through the contact structure CT, while the fourth field plate FP4 added in this embodiment is connected to the second field plate FP2 through the contact structure CT. Seen from the sectional view, the fourth field plate FP4 is closer to the position where the drain doping region DR is located than the second field plate FP2 in the horizontal direction. In this embodiment, the drain doping region DR is located on the right side of the second field plate FP2 and the fourth field plate FP4, while the right side of the fourth field plate FP4 is closer to the right side than the right side of the second field plate FP2 in the horizontal direction. That is, a part of the fourth field plate FP4 partially protrudes from the right side of the second field plate FP2.

As mentioned above, if the first field plate FP1 is extended to be close to the drain doped region DR, it may cause TDDB in the drain doped region DR and further affect the first field plate FP1. Therefore, the second field plate FP2 is added in the above-mentioned second embodiment, and the second field plate FP2 is far away from the drain doping region DR, so the occurrence probability of TDDB can be reduced. However, as the size of the semiconductor device becomes smaller and smaller, the thickness of the first dielectric layer 44 may become thinner and thinner, and the high voltage of the drain doped region DR may penetrate through the first dielectric layer 44 and then affect the diagonally upper second field plate FP2. Therefore, in order to avoid the above situation, the second field plate FP2 in this embodiment is shorter in the horizontal direction than the second field plate FP2 in the above-mentioned second embodiment, and the second field plate FP2 is electrically connected to the fourth field plate FP4 through the contact structure CT, so the fourth field plate FP4 can be regarded as an extension of the second field plate FP2. In this embodiment, the field plate closest to the drain doped region DR is the fourth field plate FP4. However, because the fourth field plate FP4 and the drain doped region DR are separated by the first dielectric layer 44 and the second dielectric layer 46, the distance d2 between the fourth field plate FP4 and the drain doped region DR is farther than the distance d1 between the second field plate FP2 and the drain doped region DR (refer to FIG. 2) in the above-mentioned second embodiment, and this embodiment can further reduce TDDB. In addition, in this embodiment, a part of the first metal layer M1 is used as the second field plate FP2 and the fourth field plate FP4, so although the fourth field plate FP4 is added, compared with the above-mentioned second embodiment, the actual process steps in this embodiment will not be increased.

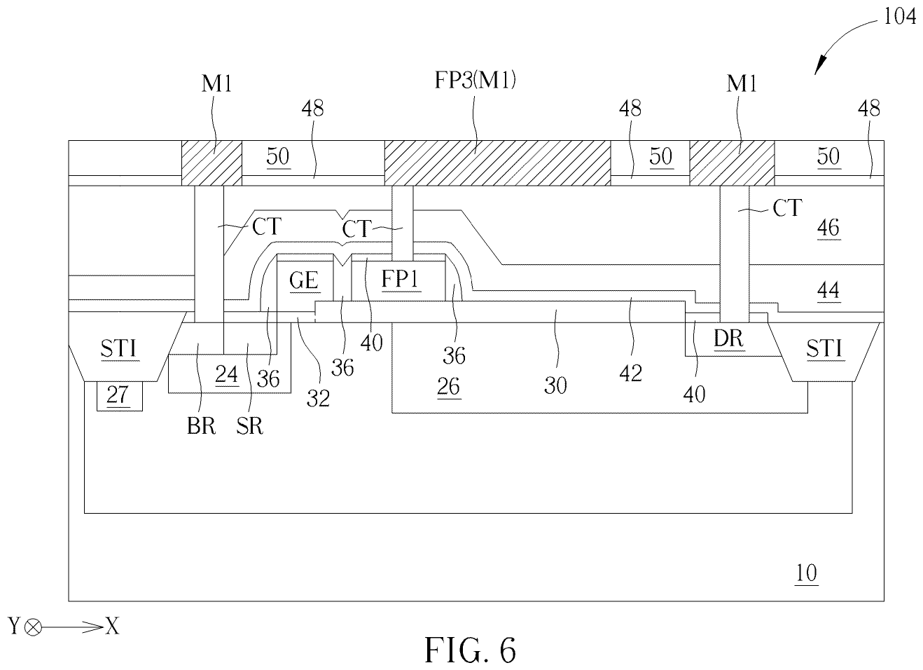

Next, please refer to FIG. 6, which shows a schematic cross-sectional structure of a semiconductor structure according to a fourth embodiment of the present invention. As shown in FIG. 6, in an embodiment of the present invention, a semiconductor structure 104 is provided, wherein the semiconductor structure 104 may not include the second field plate FP2 located between the first dielectric layer 44 and the second dielectric layer 46, but only include the third field plate FP3. As shown in FIG. 6, the third field plate FP3 in this embodiment is electrically connected with the first field plate FP1 through the contact structure CT, that is to say, the third field plate FP3 can be electrically connected with the first field plate FP1 as an extension of the first field plate FP1, and when the first field plate FP1 is subsequently biased, the voltage passing through the third field plate FP3 can also be controlled together, thereby controlling the electric field of the drift region 26 below the third field plate FP3. Alternatively, in other embodiments, the third field plate FP3 does not necessarily need to be electrically connected with the first field plate FP1, and the third field plate FP3 can be independently connected with another voltage source to independently control the lower drift region 26, which is also within the scope of the present invention.

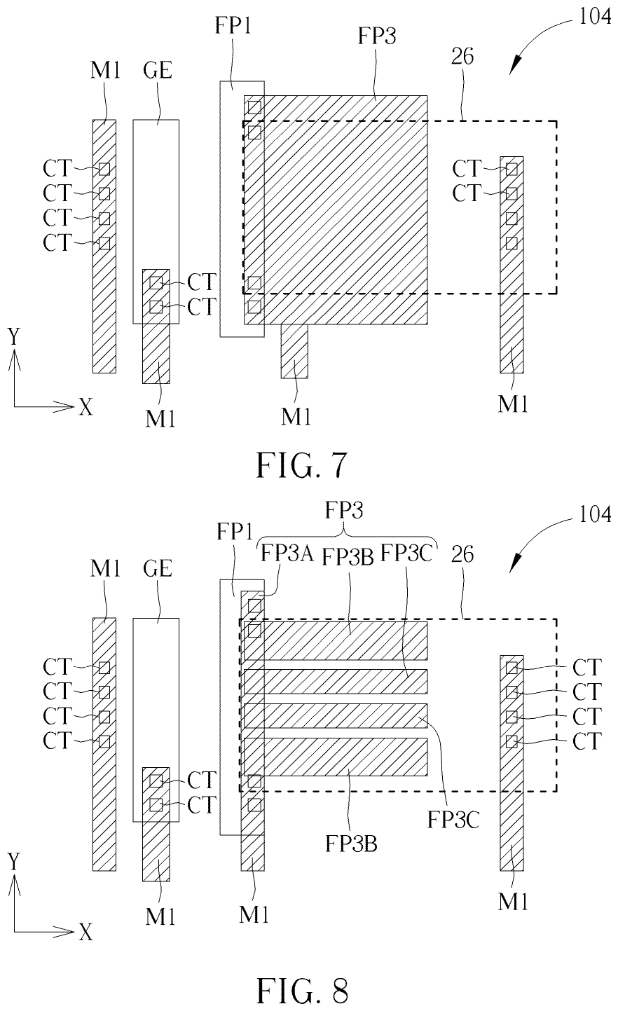

Please also refer to FIG. 7, which shows the top view of the metal layer, gate electrode and field plate in FIG. 6. It is worth noting that, for the sake of simplicity, only a part of the elements, such as the first drift region 26, the metal layer M1, the gate electrode GE, the contact structure CT, the first field plate FP1 and the second field plate FP2, are depicted in FIG. 7, and the rest of the elements are omitted from the drawing, so they will be described here first. As shown in FIG. 7, from the top view, the third field plate FP3 may have a rectangular shape, and part of the second field plate FP2 covers right above the drift region 26, so the electric field in the lower drift region 26 can be controlled by applying a bias voltage to the second field plate FP2. However, the applicant found that in the above-mentioned structure, if the third field plate FP3 is designed into a rectangular shape, although it is beneficial to control the electric field, because the area occupied by the third field plate FP3 is large, it will also cause the element resistance of the semiconductor structure to increase, which is not conducive to the electric energy conversion efficiency of the element.

In order to appropriately reduce the resistance of the semiconductor structure, the fifth embodiment of the present invention is proposed. Please refer to FIG. 8, which shows the top view of the metal layer, gate electrode and field plate of the semiconductor structure of the fifth embodiment of the present invention. In FIG. 8, most of the elements are the same as those shown in the above-mentioned FIG. 7, so these elements are not repeated here. In addition, for the sake of simplicity, some components in FIG. 8 are omitted from the drawing, which will be described here first. In addition, the cross-sectional view of the semiconductor structure 105 in FIG. 8 is the same as that in FIG. 6 of the fourth embodiment, so it is also possible to refer to FIG. 6 without repeating the details.

In this embodiment, the third field plate FP3 is not designed in a rectangular shape, but in a shape similar to a comb, wherein the third field plate FP3 includes a main shaft part FP3A and a plurality of branch parts FP3B and branch parts FP3C. The branch parts FP3B and branch parts FP3C are connected to the main shaft part FP3A, wherein the extending direction of the main shaft part is perpendicular to the extending direction of the branch parts, for example, in this embodiment, the main shaft part FP3A extends along the Y axis, while the branch parts FP3B and FP3C extend along the X axis. In addition, a plurality of branch parts FP3B and a plurality of branch parts FP3C are arranged in parallel with each other along the Y-axis direction, and the difference between the branch part FP3B and the branch part FP3C is that the branch part FP3B is located at both ends of a plurality of branch parts arranged in parallel along the Y-axis direction, that is, the two branch parts are defined as FP3B and the other branch parts are defined as FP3C as viewed from FIG. 8.

In this embodiment, the third field plate FP3 is designed in a comb shape, which can reduce the coverage area of the third field plate FP3 and further reduce the overall resistance of the semiconductor structure. Although the ability of the third field plate FP3 in this embodiment to control the electric field is slightly lower than that of the rectangular third field plate FP3 in the above-mentioned fourth embodiment, this embodiment can effectively reduce the resistance of the semiconductor structure, thereby improving the power conversion efficiency.

In addition, in this embodiment, the extending direction (e.g., X axis) of the branch parts FP3B and FP3C and the connecting line direction from the source S to the drain D are parallel to each other. Since the direction of the electric field is the direction of the connecting line from the source S to the drain D, the extension directions of the branch parts FP3B and FP3C are designed to be parallel to the flow direction of the electric field, so that there is less obstruction of elements in the flow path of the electric field, and the resistance value of the semiconductor structure can be further reduced.

In addition, in this embodiment, the width of the branch part FP3B can be designed to be larger than that of other branch parts FP3C, that is, as shown in FIG. 8, the width of the branch part FP3B (the width in the Y-axis direction) can be larger than that of other branch parts FP3C (the width in the Y-axis direction). Because in the actual manufacturing process, the boundary of the device often suffers from more etching damage due to the load effect, the branch part at the boundary is designed to have a larger width, which can make the surrounding branch part have a relatively stable structure and avoid damage.

It is worth noting that the third field plate FP3 described in the above fifth embodiment has a special shape from the top view, and it also has corresponding advantages, such as reducing the resistance value of elements. Although in the above-mentioned fifth embodiment, the semiconductor structure 104 contains only the first field plate FP1 and the third field plate FP3, it can be understood that in other embodiments of the present invention, the field plate with special top view shape of the above-mentioned fifth embodiment can also be combined with other field plates, for example, the second or third embodiment can be combined with the fifth embodiment, that is to say, the semiconductor structure may have a first field plate FP1, a second field plate FP2, a third field plate FP3 and a fourth field plate FP4, and the third field plate FP3 may also have a comb shape. This variation is also within the scope of the present invention.

Based on the above description and drawings, the present invention provides a semiconductor structure, which includes a substrate 10, an oxide layer 30 located on one surface of the substrate 10, a gate electrode GE located on the substrate 10 and partially contacting the substrate 10, a first field plate FP1 located on the oxide layer 30, a first dielectric layer 44 covering the gate electrode GE, and a second dielectric layer 44. A second field plate FP2 is located between the first dielectric layer 44 and the second dielectric layer 46, and a third field plate FP3 is located on the second dielectric layer 46, wherein a horizontal position of the second field plate FP2 is located between a horizontal position of the first field plate FP1 and a horizontal position of the third field plate FP3 when viewed from a cross-sectional view (refer to the embodiments shown in FIGS. 2 to 5).

In some embodiments of the present invention, a first metal layer M1 is further included on the second dielectric layer 46, wherein the third field plate FP3 and the first metal layer M1 are aligned with each other in a horizontal direction.

In some embodiments of the present invention, the first field plate FP1, the second field plate FP2 and the third field plate FP3 are electrically connected to each other.

In some embodiments of the present invention, a resistance layer R is located between the first dielectric layer 44 and the second dielectric layer 46, wherein the resistance layer R is electrically connected to the first metal layer M1, and the material of the resistance layer R is the same as that of the second field plate FP2.

In some embodiments of the present invention, a first doped region (the source doped region SR) and a second doped region (the drift region 26) are located in the substrate, and a source S is electrically connected to the first doped region SR, and part of the gate electrode GE and the oxide layer 30 are located on the second doped region 26.

In some embodiments of the present invention, the second field plate FP2 is located directly above the second doped region 26.

In some embodiments of the present invention, a third doped region (the drain doped region DR) is located in the second doped region 26, and a drain Dis electrically connected to the third doped region DR.

In some embodiments of the present invention, the first doped region SR, the second doped region 26 and the third doped region DR have the same conductivity type.

In some embodiments of the present invention, the second field plate FP2 has a first portion FP2A extending in an oblique direction and a second portion FP2B extending in a horizontal direction.

In some embodiments of the present invention, a fourth field plate FP4 is located on the second dielectric layer 46, wherein the fourth field plate FP4 is electrically connected with the second field plate FP2, and the fourth field plate FP4 and the third field plate FP3 are aligned with each other in a horizontal direction.

The present invention further provides a semiconductor structure 105, which comprises a substrate 10, an oxide layer 3 located on a surface of the substrate 10, a gate electrode GE located on the substrate 10 and partially contacting the substrate 10, a first field plate FP1 located on the oxide layer 30, and a third field plate FP3 located above the first field plate FP3, wherein, from a top view, it comprises a main shaft part FP3A extending along a first direction (Y-axis direction) and a plurality of branch parts FP3B and FP3C extending along a second direction, wherein the branch parts FP3B and FP3C are connected with the main shaft part FP3A (please refer to the embodiment shown in FIG. 8).

In some embodiments of the present invention, the semiconductor structure 105 further includes a source S and a drain D, and a connection direction between the source S and the drain D is defined as the second direction (X-axis direction), and the first direction is preferably perpendicular to the second direction.

In some embodiments of the present invention, a plurality of branch parts FP3B, FP3C are arranged in parallel with each other, and the widths of the two branch parts FP3B arranged closest to the boundary among the plurality of branch parts are larger than the widths of other branch parts FP3C.

In some embodiments of the present invention, a first metal layer M1 is further included, and viewed from a cross section, the first metal layer M1 and the third field plate FP3 are aligned in a horizontal direction.

The present invention also provides a method for forming a semiconductor structure, which includes providing a substrate 10, forming an oxide layer 30 on one surface of the substrate 10, forming a gate electrode GE on the substrate 10 and partially contacting the substrate 10, forming a first field plate FP1 on the oxide layer 30, forming a first dielectric layer 44 covering the gate electrode GE, and forming a second dielectric layer 46 on the first dielectric layer 44, a second field plate FP2 is formed between the first dielectric layer 44 and the second dielectric layer 46, and a third field plate FP3 is formed on the second dielectric layer 46, wherein a horizontal position of the second field plate FP2 is between a horizontal position of the first field plate FP1 and a horizontal position of the third field plate FP3 when viewed from a cross section.

In some embodiments of the present invention, a first metal layer M1 is formed on the second dielectric layer 46, wherein the third field plate FP3 and the first metal layer M1 are aligned with each other in a horizontal direction.

In some embodiments of the present invention, a resistance layer R is formed between the first dielectric layer 44 and the second dielectric layer 46, wherein the resistance layer R is electrically connected to the first metal layer M1, and the material of the resistance layer R is the same as that of the second field plate FP2.

In some embodiments of the present invention, the resistance layer R is formed at the same time as the second field plate FP2.

In some embodiments of the present invention, it further includes forming a first doped region (the source doped region SR) and a second doped region (the drift region 26) in the substrate 10, forming a source S electrically connected to the first doped region SR, wherein part of the gate electrode GE and the oxide layer 30 are located on the second doped region 26, and forming a third doped region (the drain doped region DR) in the second doped region 26, and forming a drain D electrically connected to the third doped region DR.

In some embodiments of the present invention, a fourth field plate FP4 is formed on the second dielectric layer 46, wherein the fourth field plate FP4 is electrically connected with the second field plate FP2, and the fourth field plate FP4 and the third field plate FP3 are aligned with each other in a horizontal direction.

To sum up, the invention is characterized in that the field plate located in LDMOS can regulate the electric field in the drift region and reduce the probability of electric field breakdown, so it is an important element in LDMOS. However, the applicant found that the larger the field plate is designed, the more effectively the electric field in the drift region can be controlled, but at the same time, it may also increase the field plate too close to the drain doped region, so that the electric field in the drain doped region will affect the field plate. Therefore, in some embodiments of the present invention, an improved semiconductor structure is proposed, especially a high-voltage lateral double-diffused metal-oxide-semiconductor (HV-LDMOS) transistor element with multiple field plates. In some embodiments, the second field plate is located between the two dielectric layers above the drift region, so the second field plate can not only control the electric field of the drift region, but also avoid the problem of TDDB caused by being too close to the drain doped region. In other embodiments of the present invention, the fourth field plate is located above the dielectric layer and connected to the second field plate, further reducing the occurrence probability of TDDB in the drain doped region. In other embodiments of the present invention, the shape of the third field plate is designed, for example, it is designed as a comb shape, so that the overall resistance of the semiconductor structure can be reduced. The embodiments provided by the invention have the advantages of improving the quality of semiconductor elements and the electric energy conversion efficiency.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure comprising:
a substrate;
an oxide layer located on a surface of the substrate;
a gate electrode located on the substrate and partially contacting the substrate, and partially located on the oxide layer;
a first field plate located on the oxide layer;
a first dielectric layer covering the gate electrode;
a second dielectric layer located on the first dielectric layer;
a second field plate located between the first dielectric layer and the second dielectric layer; and
a third field plate located on the second dielectric layer, wherein a horizontal position of the second field plate is located between a horizontal position of the first field plate and a horizontal position of the third field plate when viewed from a sectional view.

2. The semiconductor structure according to claim 1, further comprising a first metal layer located on the second dielectric layer, wherein the third field plate and the first metal layer are aligned with each other in a horizontal direction.

3. The semiconductor structure according to claim 1, wherein the first field plate, the second field plate and the third field plate are electrically connected to each other.

4. The semiconductor structure according to claim 2, further comprising a resistance layer located between the first dielectric layer and the second dielectric layer, wherein the resistance layer is electrically connected to the first metal layer, and the material of the resistance layer is the same as the material of the second field plate.

5. The semiconductor structure according to claim 1, further comprising a first doped region and a second doped region located in the substrate, and a source electrically connected to the first doped region, wherein part of the gate electrode and the oxide layer are located on the second doped region.

6. The semiconductor structure according to claim 5, wherein the second field plate is located directly above the second doped region.

7. The semiconductor structure according to claim 5, further comprising a third doped region located in the second doped region and a drain electrically connected to the third doped region.

8. The semiconductor structure according to claim 7, wherein the first doped region, the second doped region and the third doped region have the same conductivity type.

9. The semiconductor structure according to claim 1, wherein the second field plate has a first portion extending in an oblique direction and a second portion extending in a horizontal direction.

10. The semiconductor structure according to claim 1, further comprising a fourth field plate located on the second dielectric layer, wherein the fourth field plate is electrically connected to the second field plate, and the fourth field plate and the third field plate are aligned with each other in a horizontal direction.

11. A semiconductor structure comprising:
a substrate;
an oxide layer located on a surface of the substrate;
a gate electrode located on the substrate and partially contacting the substrate, and partially located on the oxide layer;
a first field plate located on the oxide layer; and
a third field plate located above the first field plate, wherein the third field plate presents a comb shape when viewed from a top view, and the third field plate comprises a main shaft part extending along a first direction and a plurality of branch parts extending along a second direction, wherein the branch parts are connected with the main shaft part.

12. The semiconductor structure according to claim 11, wherein the semiconductor structure further comprises a source and a drain, and a connection direction between the source and the drain is defined as the second direction, and the first direction is preferably perpendicular to the second direction.

13. The semiconductor structure according to claim 11, wherein the plurality of branch parts are arranged in parallel with each other, and the widths of the two branch parts arranged closest to a boundary among the plurality of branch parts are larger than those of other branch parts.

14. The semiconductor structure according to claim 11, further comprising a first metal layer, and the first metal layer and the third field plate are aligned in a horizontal direction from a cross-sectional view.

15. A method for forming a semiconductor structure, comprising:
providing a substrate;
forming an oxide layer on a surface of the substrate;
forming a gate electrode on the substrate and partially contacting the substrate, and partially on the oxide layer;
forming a first field plate on the oxide layer;
forming a first dielectric layer covering the gate electrode;
forming a second dielectric layer on the first dielectric layer;
forming a second field plate between the first dielectric layer and the second dielectric layer; and
forming a third field plate on the second dielectric layer, wherein a horizontal position of the second field plate is between a horizontal position of the first field plate and a horizontal position of the third field plate when viewed from a cross section.

16. The method for forming a semiconductor structure according to claim 15, further comprising forming a first metal layer on the second dielectric layer, wherein the third field plate and the first metal layer are aligned with each other in a horizontal direction.

17. The method for forming a semiconductor structure according to claim 16, further comprising forming a resistance layer between the first dielectric layer and the second dielectric layer, wherein the resistance layer is electrically connected with the first metal layer, and the material of the resistance layer is the same as the material of the second field plate.

18. The method for forming a semiconductor structure according to claim 17, wherein the resistance layer and the second field plate are formed at the same time.

19. The method for forming a semiconductor structure according to claim 15, further comprising:
forming a first doped region and a second doped region in the substrate;
forming a source electrically connected to the first doped region, wherein part of the gate electrode and the oxide layer are located on the second doped region;
forming a third doped region in the second doped region; and
forming a drain electrically connected to the third doped region.

20. The method for forming a semiconductor structure according to claim 15, further comprising forming a fourth field plate on the second dielectric layer, wherein the fourth field plate is electrically connected with the second field plate, and the fourth field plate and the third field plate are aligned with each other in a horizontal direction.
